(19) United States
(12) Patent Application Publication
(10) Pub. No.: US 2014/0175618 A1
(43) Pub. Date: Jun. 26, 2014

(54) TRANSITION METAL ALUMINATE AND HIGH K DIELECTRIC SEMICONDUCTOR STACK

(71) Applicant: Intermolecular Inc., (US)

(72) Inventor: Salil Mujumdar, San Jose, CA (US)

(73) Assignee: Intermolecular Inc., San Jose, CA (US)

(21) Appl. No.: 13/723,853

(22) Filed: Dec. 21, 2012

(51) Int. Cl. H01L 21/02

(52) U.S. Cl. CPC H01L 21/02178
USPC 257/644; 438/763

(57) ABSTRACT

Methods of forming a high K dielectric semiconductor stack are described. A semiconductor substrate is provided, in which the native oxide layer is removed. A transition metal aluminate layer is deposited onto the semiconductor substrate across discrete multiple regions in a combinatorial manner. A high K dielectric layer is deposited onto the transition metal aluminate layer across the discrete multiple regions in a combinatorial manner. The transition metal aluminate layer and the high K dielectric layer are patterned to form a plurality of high K dielectric semiconductor stacks across discrete multiple regions. A three-five semiconductor substrate or a germanium substrate can be used in methods of forming a high K dielectric semiconductor stack.

### BACKGROUND

Germanium semiconductor substrates can be used in place of silicon semiconductor substrates especially for low voltage applications and high frequency applications. Three-five (III-V) semiconductor substrates, such as substrates containing a combination of a IIIA and a VA element can also be used for similar applications. Diffusion of the substrate material into an overlying dielectric layer tends to be more of a concern with Germanium and III-V semiconductor substrates, as compared with a silicon substrate.

Current diffusion barriers for the above mentioned substrate types tend to be unstable and/or have a low k dielectric value, which limits the ability to achieve ultrathin equivalent oxide thickness (EOT) stacks. It is within this context that the embodiments arise.

### SUMMARY

In some embodiments, a method of forming a high K dielectric semiconductor stack is described. A germanium semiconductor substrate is provided, in which the native oxide layer is removed. A transition metal aluminate layer is deposited onto the germanium semiconductor substrate across site-isolated regions in a combinatorial manner. A high K dielectric layer is deposited onto the transition metal aluminate layer across the discrete site-isolated regions in a combinatorial manner. The transition metal aluminate layer and the high K dielectric layer are patterned to form a plurality of high K dielectric semiconductor stacks across the discrete site-isolated regions on the germanium semiconductor substrate.

In some embodiments, a high K dielectric semiconductor device is described. A semiconductor substrate, comprising a three-five semiconductor substrate is given. As used herein, “III-V” or three-five will be understood to refer to materials made of elements from Group-IIIA and Group VA of the Periodic Table. These terms are to be considered equivalent and will be used interchangeably. A variable amount of aluminum oxide and a variable amount of transition metal oxide are deposited onto the semiconductor substrate to form a transition metal aluminate layer. The transition metal aluminate layer has a higher band gap than the transition metal oxide alone. A transition metal oxide layer is deposited onto the transition metal aluminate layer. A plurality of gate stacks is defined on the semiconductor substrate in some embodiments.

In some embodiments, a method of forming a plurality of semiconductor stacks is described. A semiconductor wafer is provided, in which the native oxide layer has been removed. A transition metal aluminate layer is deposited across site-isolated regions of the semiconductor wafer in an combinatorial process. A high K dielectric layer is deposited onto the transition metal aluminate layer across the site-isolated regions of the semiconductor wafer in an combinatorial process. The transition metal aluminate layer and the high K dielectric layer are to form a plurality of high K dielectric semiconductor stacks on the semiconductor wafer.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a schematic diagram, which illustrates an implementation of combinatorial processing and evaluation according to some embodiments.

FIG. 2 is a schematic diagram illustrating a general methodology for combinatorial process sequence integration according to some embodiments.

FIGS. 3A-3D are block diagrams illustrating a semiconductor substrate according to some embodiments.

FIG. 4 is a flow chart illustrating a method of forming a plurality of semiconductor stacks according to some embodiments.

FIG. 5 is a flow chart illustrating a method of forming a high K dielectric semiconductor stack according to some embodiments.

### DETAILED DESCRIPTION

Semiconductor manufacturing may include a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization, and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices, such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing, such as etching and cleaning. HPC processing techniques have also been successfully adapted to deposition processes, such as physical vapor deposition (PVD), atomic layer deposition (ALD), and chemical vapor deposition (CVD).

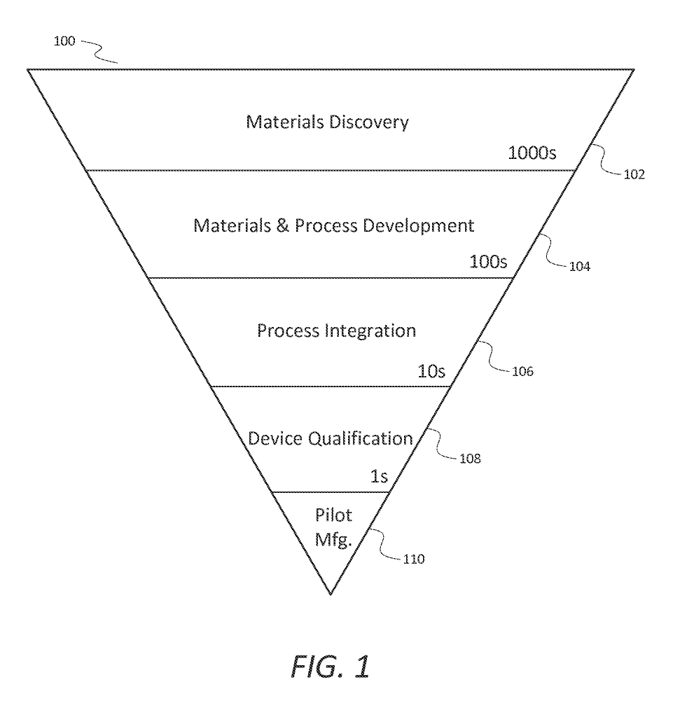

FIG. 1 is a schematic diagram 100, which illustrates an implementation of combinatorial processing and evaluation using primary, secondary, and tertiary screening. The schematic diagram 100 illustrates the relative number of combinatorial processes that run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage, performed using primary screening techniques. Primary screening techniques may include dividing substrates into coupons and depositing materials using varied processes. The materials are then evaluated and promising candidates are advanced to the secondary screen, such as a materials and process development stage 104. Evaluation of the materials is performed using metrology tools such as electronic testers and imaging tools, e.g. microscopes.

The materials and process development stage 104 may evaluate hundreds of materials (i.e., a magnitude smaller than the primary stage) and may focus on the processes used to deposit or develop those materials. Promising materials and processes are again selected and advanced to the tertiary screen, such as a process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification stage 108. In device qualification stage 108, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing stage 110.

The schematic diagram 100 is an example of various techniques that may be used to evaluate and select materials and processes for the development of new materials and processes. The descriptions of primary, secondary, etc. screening and the various stages, 102-110 are arbitrary and the stages may overlap, occur out of sequence, or be described and performed in many other ways.

The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than just considering a series of local optimums, i.e., where the best conditions and materials for each manufacturing unit operation is considered in isolation, the embodiments described herein consider interaction effects introduced due to the multitude of processing operations that are performed and the order in which such multitude of processing operations are performed when fabricating a device. A global optimum sequence order is therefore derived and as part of this derivation, the unit processes, unit process parameters, and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate, which are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants, and location of structures within each region are designed to enable valid statistical analysis of the test results within each region and across regions to be performed.

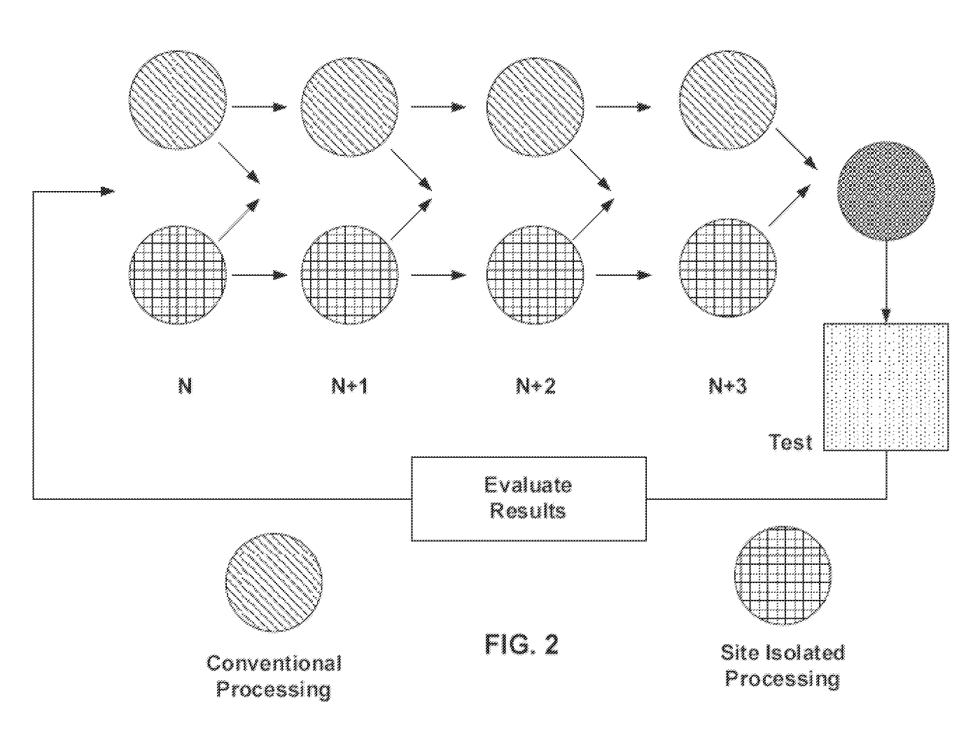

FIG. 2 is a simplified schematic diagram illustrating a general methodology for combinatorial process sequence integration that includes site isolated processing and/or conventional processing in accordance with an embodiment of the invention. The substrate is initially processed using conventional process N. In an exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed, such that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

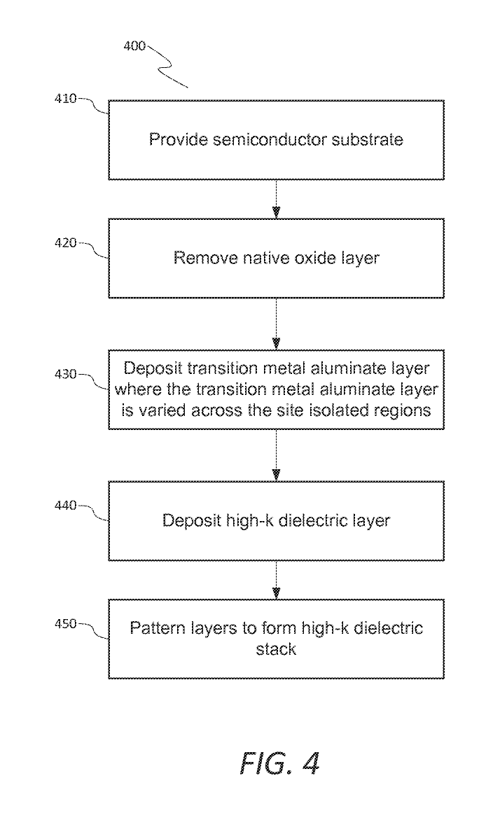

It should be appreciated that various other combinations of conventional and combinatorial processes can be included in the processing sequence with regard to FIG. 4. For instance, the combinatorial process sequence integration can be applied to any desired segments and/or portions of an overall process flow. Characterization, including physical, chemical, acoustic, magnetic, electrical, optical, etc. testing can be performed after each process operation and/or series of process operations within the process flow, as desired. The feedback provided by the testing is used to select certain materials, processes, process conditions, and process sequences and eliminate others. Furthermore, the above flows can be applied to entire monolithic substrates or portions of monolithic substrates, such as coupons.

Under combinatorial processing operations, the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and are not meant to be an exhaustive list, as other process parameters used in semiconductor manufacturing may be varied.

As mentioned above, within a region, the process conditions are substantially uniform, in contrast to gradient processing techniques which rely on the inherent non-uniformity of the material deposition. That is, the embodiments described herein may locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in some embodiments or the regions may be isolated and therefore, non-overlapping. When the regions are adjacent, there may be a slight overlap wherein the materials or precise process interactions are not known; however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

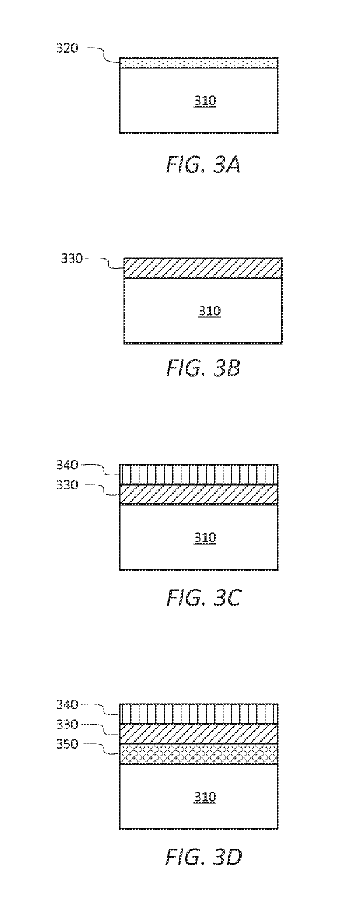

FIGS. 3A-3D are block diagrams, illustrating a semiconductor substrate 310 according to some embodiments of the invention. The semiconductor substrate 310 includes one of germanium or a three-five substrate, in some embodiments. A native oxide layer 320 may form on the surface of the substrate 310. With regard to a germanium substrate, germanium oxide tends to be unstable as the germanium oxide is water soluble and has a maximum operating temperature of approximately 400-450 degrees C. Accordingly, the germanium oxide layer is removed through a suitable etching process that removes the oxide layer to expose the substrate layer.

A transition metal aluminate (TAlO) layer 330 is deposited onto the substrate 310, after removal of the native oxide layer 320. In some embodiments, the TAlO layer 330 can be deposited by atomic layer deposition, in which alumina (Al₂O₃) is combined with a transition metal oxide, such as hafnium oxide. It will be appreciated by one skilled in the art that the combining of the alumina with the transition metal oxide may be achieved by a combination of precursor fluids in some embodiments. It should be further appreciated that the TAlO layer 330 significantly reduces germanium inter-diffusion into an overlying high K dielectric layer. The TAlO layer 330 is more effective at preventing germanium inter-diffusion than alumina alone, and much more effective than germanium oxide. In addition, the combination of alumina with a transition metal oxide increases the band gap level, compared to a transition metal oxide layer alone. The band gap level can be adjusted by varying the aluminum oxide content and this adjusting may be accomplished combinatorially through site isolated processing as discussed with reference to FIGS. 1-2. In addition, the combinatorial vacuum deposition equipment owned by the assignee may be utilized to carry out the processing techniques described herein. It should be appreciated that the ability to adjust the band gap level through the varying of the aluminum oxide assists in reducing the gate leakage current, whereas a transition metal oxide layer is not capable of enabling this adjustment.

In addition, the dielectric constant of TAlO is higher than alumina, which can reduce the equivalent oxide thickness, compared to using alumina alone. That is, the higher dielectric constant for the TAlO provides the same properties and advantages of a silicon oxide layer, but with thicker films while maintaining or lowering the equivalent oxide thickness (EOT). The concentrations of alumina and transition metal oxide can also be varied combinatorially as described with reference to FIGS. 1-2. It should be appreciated that varying the concentrations enables the ability to achieve a customized TAlO level according to design specifications. In addition, the varying allows tuning of the flat band voltage by adjusting the aluminum profile of the TAlO layer. It should be appreciated that the flat band voltage is the applied voltage necessary to produce a flatband condition. It should be appreciated that the tuning of the flat band voltage enables that ability to provide a more desirable threshold voltage so as to offset flat band voltage shifts related to the use of high K dielectrics. Work function tuning is important to reach Vt (threshold voltage) targets depending on the technology, (e.g. High voltage vs. Low voltage), and application type (e.g. high performance vs. low power).

Still referring to FIGS. 3A-3C, a transition metal oxide layer 340 is deposited, such as hafnium oxide The transition metal oxide layer 340 may be deposited by in-situ deposition, such as atomic layer deposition in some embodiments. Forming gas annealing of the deposited transition metal oxide layer 340 lowers the interface trap density. In some embodiments, the forming gas annealing utilizes a nitrogen and hydrogen atmosphere. The hydrogen permeates into the dielectric layer to passivate the germanium layer. In addition, the hydrogen penetrates into the dielectric to alleviate dangling bonds and provide a high quality interface for deposition of a high K dielectric. Lowering interface trap density is important for improving mobility of carriers in the channel. The mobility translates to transistor current output and, in turn, circuit speed. In some embodiments, as illustrated in FIG. 3D, an alumina layer 350 can be deposited directly onto the substrate 310, prior to depositing the TAlO layer 330 and the transition metal oxide layer 340, to form a tri-layer dielectric. Alumina (Al₂O₃) is non-reactive with a germanium substrate and provides an additional barrier to diffusion of germanium into the overlying high K dielectric layer 330 where the semiconductor substrate 310 includes germanium.

In some embodiments, the semiconductor substrate 310 may comprise a three-five semiconductor substrate. A three-five semiconductor substrate comprises one element from the IIIA group, such as boron, aluminum, gallium, or indium and one element from the VA group, such as nitrogen, phosphorus, arsenic, or antimony. Some of the common combinations are GaAs, InGaAs, InAlAs, and InP. Ratios of different materials can be varied based on application. As discussed above, any native oxide layer 320 is removed from the semiconductor substrate 310. A TAlO layer 330 is deposited, followed by a transition metal oxide layer 340. An additional embodiment deposits an alumina layer 350 directly onto the three-five semiconductor substrate 310, prior to the TAlO layer 330 and the transition metal oxide layer 340.

The resulting layered semiconductor substrate of FIG. 3C or 3D can then be patterned to form a plurality of gates on discrete regions of substrate 310 in some embodiments. The deposited layers, 330, 340, and 350, can be formed combinatorially, using the apparatus and methods discussed above with reference to FIGS. 1-2. It should be appreciated that while the gates are described as being combinatorially formed in some embodiments, this is not meant to be limiting. That is, the techniques may be applied to conventional semiconductor processing techniques as well.

FIG. 4 is a flow chart illustrating a method 400 of forming a plurality of semiconductor stacks, according to some embodiments of the invention. A semiconductor wafer is provided in step 410. In some embodiments, regions of the semiconductor wafer may be site isolated to support combinatorial processing as described above. A native oxide layer is removed from the semiconductor wafer in step 420. A transition metal aluminate layer is deposited on a surface of the semiconductor wafer in step 430. The transition metal aluminate layer can be deposited across site-isolated regions in a combinatorial process in some embodiments. A high K dielectric layer is deposited onto the transition metal aluminate layer in step 440. The high K dielectric layer may be deposited across the site-isolated regions in a combinatorial process in some embodiments. The transition metal aluminate layer and the high K dielectric layer are patterned in step 450 to form a plurality of high K dielectric semiconductor stacks on the semiconductor wafer in site isolated regions.

In some embodiments, the semiconductor wafer comprises germanium. In some embodiments, the semiconductor wafer comprises a three-five semiconductor wafer. The transition metal aluminate layer may be deposited by combining aluminum oxide with a transition metal oxide, as mentioned above. The k value and/or the band gap level of the transition metal aluminate layer can be adjusted by adjusting the aluminum oxide level and/or the transition metal oxide level. Thus, the embodiments when integrated with combinatorial processing techniques provide a wealth of information on a single substrate in an attempt to identify a suitable combination.

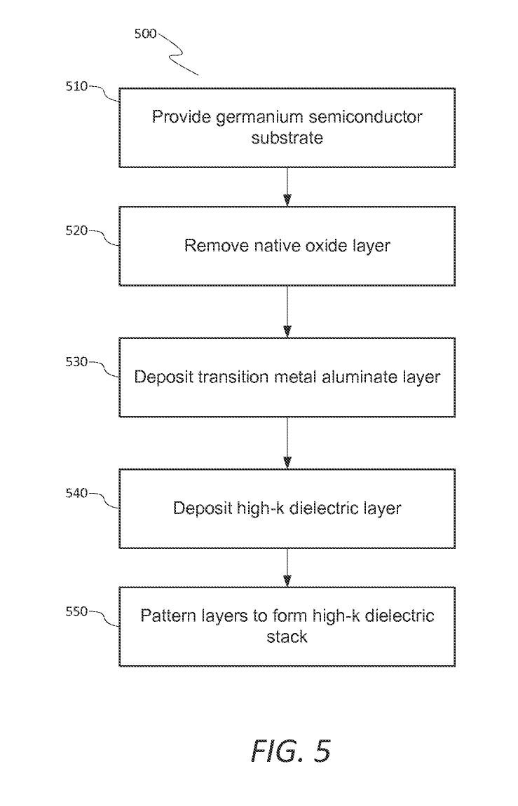

FIG. 5 is a flow chart, illustrating a method of forming a high K dielectric semiconductor stack 500. A germanium semiconductor substrate is provided in step 510. A native oxide layer is removed from the germanium semiconductor substrate in step 520. In some embodiments, a thin layer of aluminum oxide is deposited onto the germanium semiconductor substrate, after the native oxide layer has been removed and prior to any additional layer depositions. However, it should be appreciated that this layer of aluminum oxide is optional.

A transition metal aluminate layer is deposited onto the germanium semiconductor substrate in step 530. The transition metal aluminate layer can be deposited by atomic layer deposition or other suitable deposition process. The transition metal aluminate layer is deposited independently across site-isolated regions of the germanium semiconductor substrate in a combinatorial manner in some embodiments. The transition metal aluminate layer may be deposited by alloying or mixing aluminum oxide with a transition metal oxide during the deposition process. In some embodiments, the transition metal oxide includes hafnium oxide. In some embodiments, the transition metal oxide includes titanium oxide or tantalum oxide. A dielectric constant, i.e., k value, of the transition metal aluminate layer can be adjusted by adjusting one or more of the aluminum oxide content or the transition metal oxide content. The band gap value of the transition metal aluminate layer can also be adjusted by adjusting one or more of the aluminum oxide level or the transition metal oxide level.

A high K dielectric layer is deposited onto the transition metal aluminate layer in step 540. The high K dielectric layer can be deposited by atomic layer deposition in some embodiments. In some embodiments, the high K dielectric layer includes a transition metal oxide layer. The high K dielectric layer is deposited onto the transition metal aluminate layer independently across the discrete multiple regions of the germanium semiconductor substrate in a combinatorial manner in some embodiments. The transition metal aluminate layer and the high K dielectric layer are patterned to form a plurality of high K dielectric semiconductor stacks for an associated plurality of integrated circuits on the germanium semiconductor substrate in step 550. The transition metal aluminate layer and the high K dielectric layer are patterned across the discrete multiple regions of the germanium semiconductor substrate. The density of interface traps can be lowered in the transition metal aluminate layer by forming gas annealing of the layer stack after depositing the high K dielectric layer. As used herein transition metals include any of the metallic elements within Groups IIIB to IIB in the Periodic Table. Transition metals tend to form alloys easily, have relatively high inching points, and have more than one valence because of their incomplete inner shells.

Some embodiments provide a transition metal aluminate layer that minimizes germanium or three-five transition metal diffusion into the high K dielectric layer. In addition, the combining of an aluminum oxide with the transition metal oxide increases the band gap as compared to a transition metal oxide layer alone. The increased band gap assists in reducing gate leakage current. Increasing dielectric band gap usually results in higher barrier height. This higher barrier height then suppresses carrier tunneling mechanisms such as direct tunneling and Fowler-Nordheim tunneling and reduces gate leakage current. The k value and the band gap value of the transition metal aluminate layer can be modified by adjusting one of the aluminum oxide content or the transition metal oxide level. Through the HPC processing different combinations may be formed and tested to optimize a k value and band gap value for a particular application. Forming gas annealing (FGA) of the transition metal oxide layer reduces the interface trap density and can potentially offer a sub 1 nm EOT with acceptable interface trap density (Dᵢₜ) values, which in turn provides for gate leakage reduction for future nodes. The transition metal aluminate layer and the transition metal oxide layer can be deposited by atomic layer deposition and in some embodiments the k value and the band-gap of the overlying higher-k layer can be tuned from that of pure Al₂O₃ all the way to the higher-k TOx dielectric by switching between/shutting off the flow of Precursors during the deposition processing. Thus, the embodiments utilize known processing techniques to achieve the desired gate stack specifications and can simplify the gate stack flow.

Although the foregoing embodiments of the invention have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims. In the claims, elements and/or steps do not imply any particular order of operation, unless explicitly stated in the claims.

1. A method of forming a high K dielectric semiconductor stack, the method comprising:
defining a plurality of site-isolated regions on a surface of a substrate;
depositing a transition metal aluminate layer on each of the plurality of site-isolated regions,
wherein the transition metal aluminate layer in each of the plurality of site-isolated regions comprises aluminum oxide and transition metal oxide, and
wherein a concentration ratio of the aluminum oxide to the transition metal oxide in the transition metal aluminate layer is combinatorially varied to differ between at least two of the plurality of site-isolated regions on the surface of the substrate; and
depositing a high K dielectric layer onto each of the transition metal aluminate layers formed within the plurality of site-isolated regions.

2. The method of claim 1, further comprising depositing a layer of aluminum oxide on the substrate, prior to depositing the transition metal aluminate layer.

3. The method of claim 1, wherein the depositing the transition metal aluminate layer comprises mixing the aluminum oxide with the transition metal oxide during the depositing of the transition metal aluminate layer.

4. The method of claim 3, further comprising varying an amount of one or more of the aluminum oxide or the transition metal oxide between at least two of the plurality of site-isolated regions, thereby adjusting a k value of the transition metal aluminate layer among the plurality of site-isolated regions.

5. The method of claim 3, further comprising varying an amount of one or more of the aluminum oxide or the transition metal oxide among the plurality of site-isolated regions, thereby adjusting a band gap value of the transition metal aluminate layer among the plurality of site-isolated regions.

6. The method of claim 1, wherein the semiconductor substrate comprises a III-V semiconductor substrate.

7. The method of claim 1, wherein the high K dielectric layer comprises a transition metal oxide layer.

8. The method of claim 1, wherein the semiconductor substrate comprises germanium.

9. The method of claim 1, wherein the transition metal aluminate comprises hafnium.

10-20. (canceled)

21. The method of claim 1, further comprising, prior to depositing the transition metal aluminate layer, removing a native oxide layer from each of the plurality of site-isolated regions.

22. The method of claim 1, further comprising, after depositing the high K dielectric layer, patterning the transition metal aluminate layer and the high K dielectric layer to form a plurality of site-isolated high K dielectric semiconductor stacks on the substrate.

23. The method of claim 1, wherein the depositing of the high K dielectric layer is performed in a combinatorial manner such that a composition of the high K dielectric layer differs between at least two the plurality of site-isolated regions on the surface of the substrate.

24. The method of claim 1, wherein the depositing of the transition metal aluminate layer in each of the plurality of site-isolated regions is performed in the combinatorial manner using atomic layer deposition.

25. The method of claim 24, wherein the atomic layer deposition comprises combining an aluminum containing precursor and a transition metal containing precursor.

26. The method of claim 24, wherein the depositing of the high K dielectric layer comprises atomic layer deposition.

27. The method of claim 26, wherein the depositing of the transition metal aluminate layer and the depositing of the high K dielectric layer are performed in situ.

28. The method of claim 1, further comprising annealing the high K dielectric layer in a hydrogen containing environment.

29. The method of claim 1, further comprising measuring at least one of a k-value or a band gap level of each of the plurality of site-isolated regions and determining a target concentration ratio of the aluminum oxide to the transition metal oxide in the transition metal aluminate layer based on results of the measuring.

30. The method of claim 29, repeating the depositing of the transition metal aluminate layer and the depositing of the high K dielectric layer using the target concentration ratio of the aluminum oxide to the transition metal oxide.
